(19) United States
(12) Patent Application Publication
(10) Pub. No.: US 2022/0049350 A1
(43) Pub. Date: Feb. 17, 2022

(54) APPARATUS DESIGN FOR PHOTORESIST DEPOSITION

(71) Applicant: Applied Materials, Inc., Santa Clara, CA (US)

(72) Inventors: Farzad Houshmand, Mountain View, CA (US); Anantha Subramani, San Jose, CA (US); Kelvin Chan, San Ramon, CA (US)

(21) Appl. No.: 17/374,558

(22) Filed: Jul. 13, 2021

Related U.S. Application Data
(60) Provisional application No. 63/065,278, filed on Aug. 13, 2020.

(51) Int. Cl. C23C 16/458; H01L 21/687

(52) U.S. Cl. CPC C23C 16/4585; H01L 21/68721; C23C 16/4586

(57) ABSTRACT

In an embodiment, the a semiconductor processing tool is disclosed. In an embodiment, the semiconductor processing tool comprises a chamber, and a displaceable column that passes through a surface of the chamber. In an embodiment, the column comprises a base plate, an insulator layer over the base plate, a pedestal over the insulator layer, and an edge ring surrounding a perimeter of the ground plate, the insulator and the pedestal. In an embodiment, a fluidic path is provided between the edge ring and the pedestal.

### CROSS-REFERENCE TO RELATED APPLICATIONS

This application claims the benefit of U.S. Provisional Application No. 63/065,278, filed on Aug. 13, 2020, the entire contents of which are hereby incorporated by reference herein.

### BACKGROUND

### 1) Field

Embodiments of the present disclosure pertain to the field of semiconductor processing and, in particular, to processing tools for depositing photoresist onto a substrate with a vapor phase process.

### 2) Description of Related Art

Lithography has been used in the semiconductor industry for decades for creating 2D and 3D patterns in microelectronic devices. The lithography process involves spin-on deposition of a film (photoresist), irradiation of the film with a selected pattern by an energy source (exposure), and removal (etch) of exposed (positive tone) or non-exposed (negative tone) region of the film by dissolving in a solvent. A bake will be carried out to drive off remaining solvent.

The photoresist should be a radiation sensitive material and upon irradiation a chemical transformation occurs in the exposed part of the film which enables a change in solubility between exposed and non-exposed regions. Using this solubility change, either exposed or non-exposed regions of the photoresist is removed (etched). Now the photoresist is developed and the pattern can be transferred to the underlying thin film or substrate by etching. After the pattern is transferred, the residual photoresist is removed and repeating this process many times can give 2D and 3D structures to be used in microelectronic devices.

Several properties are important in lithography processes. Such important properties include sensitivity, resolution, lower line-edge roughness (LER), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures. Higher etch resistant materials also enable thinner films. Thinner films increase the efficiency of the lithographic process.

### SUMMARY

Embodiments of the present disclosure include methods of, and apparatuses for, depositing a photoresist on a substrate with a vapor phase process.

In an embodiment, the a semiconductor processing tool is disclosed. In an embodiment, the semiconductor processing tool comprises a chamber, and a displaceable column that passes through a surface of the chamber. In an embodiment, the column comprises a base plate, an insulator layer over the base plate, a pedestal over the insulator layer, and an edge ring surrounding a perimeter of the ground plate, the insulator and the pedestal. In an embodiment, a fluidic path is provided between the edge ring and the pedestal.

Embodiments may also include an assembly for holding a substrate in a semiconductor processing tool. In an embodiment, the assembly comprises, a base plate, an insulating layer over the base plate, a pedestal over the insulating layer, an edge ring around a perimeter of the base plate, the insulating layer, and the pedestal, and a fluidic path from the bottom of the assembly to the top of the assembly. In an embodiment, the fluidic path passes through a first channel between the base plate and the insulating layer, through a second channel between the edge ring and the insulating layer, and through a third channel between the edge ring and the pedestal.

Embodiments may also include a semiconductor processing tool that comprises, a chamber and a showerhead assembly that seals the chamber, where the showerhead assembly is electrically coupled to an RF source. In an embodiment, the processing tool further comprises a displaceable column that passes through the chamber and is opposite from the showerhead assembly. In an embodiment, the column comprises, a base plate, an insulator layer over the base plate, a pedestal over the insulator layer, and an edge ring surrounding a perimeter of the ground plate, the insulator and the pedestal. In an embodiment, a fluidic path is provided between the edge ring and the pedestal.

### BRIEF DESCRIPTION OF THE DRAWINGS

FIG. 1 is a cross-sectional illustration of a processing tool for depositing a photoresist layer over a substrate with a vapor phase process, in accordance with an embodiment of the present disclosure.

FIG. 2 is a zoomed in illustration of an edge of a displaceable column in a processing tool for depositing a photoresist layer over a substrate with a vapor phase process, in accordance with an embodiment of the present disclosure.

FIG. 3A is a zoomed in illustration of an edge of a displaceable column in a processing tool, where the shadow ring is not engaged with the edge ring, in accordance with an embodiment of the present disclosure.

FIG. 3B is a zoomed in illustration of an edge of a displaceable column in a processing tool, where the shadow ring is engaged with the edge ring, in accordance with an embodiment of the present disclosure.

FIG. 4A is a sectional view of a processing tool for depositing a photoresist layer over a substrate with a vapor phase process, in accordance with an embodiment of the present disclosure.

FIG. 4B is a sectional view of a processing tool with the pedestal removed to expose the channels in a baseplate, in accordance with an embodiment of the present disclosure.

FIG. 5 illustrates a block diagram of an exemplary computer system, in accordance with an embodiment of the present disclosure.

### DETAILED DESCRIPTION

Processing tools for depositing photoresist onto a substrate with a vapor phase process, are described. In the following description, numerous specific details are set forth of processing tools for implementing the vapor phase deposition in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

To provide context, photoresist systems used in extreme ultraviolet (EUV) lithography suffer from low efficiency. That is, existing photoresist material systems for EUV lithography require high dosages in order to provide the needed solubility switch that allows for developing the photoresist material. Organic-inorganic hybrid materials (e.g., metal oxo materials systems) have been proposed as a material system for EUV lithography due to the increased sensitivity to EUV radiation. Such material systems typically comprise a metal (e.g., Sn, Hf, Zr, etc.), oxygen, and carbon. Metal oxo based organic-inorganic hybrid materials have also been shown to provide lower LER and higher resolution, which are required characteristics for forming narrow features.

Metal oxo material systems are currently disposed over a substrate using a wet process. The metal oxo material system is dissolved in a solvent and distributed over the substrate (e.g., a wafer) using wet chemistry deposition processes, such as a spin coating process. Wet chemistry deposition of the photoresist suffers from several drawbacks. One negative aspect of wet chemistry deposition is that a large amount of wet byproducts are generated. Wet byproducts are not desirable and the semiconductor industry is actively working to reduce wet byproducts wherever possible. Additionally, wet chemistry deposition may result in non-uniformity issues. For example, spin-on deposition may provide a photoresist layer that has a non-uniform thickness or non-uniform distribution of the metal oxo molecules. Additionally, it has been shown that metal oxo photoresist material systems suffer from thickness reduction after exposure, which is troublesome in lithographic processes. Furthermore, in a spin-on process, the percentage of metal in the photoresist is fixed, and cannot be easily tuned.

Accordingly, embodiments of the present disclosure provide a processing tool that enables a vacuum deposition process for providing a photoresist layer over the wafer. The vacuum deposition process addresses the shortcomings of the wet deposition process described above. Particularly, a vacuum deposition process provides the advantages of: 1) eliminating the generation of wet byproducts; 2) providing a highly uniform photoresist layer; 3) resisting thickness reduction after exposure; and 4) providing a mechanism to tune the percentage of metal in the photoresist.

Embodiments disclosed herein include a processing tool that includes an architecture that is particularly suitable for optimizing vapor phase depositions. For example, the processing tool may include a pedestal for supporting the wafer that is temperature controlled. In some embodiments, a temperature of the pedestal may be maintained between approximately −40° C. and approximately 300° C. Additionally, an edge purge flow and shadow ring may be provided around a perimeter of the column on which the substrate is supported. The edge purge flow and shadow ring prevent the photoresist from depositing along the edge or backside of the wafer. In an embodiment, the pedestal may also provide any desired chucking architecture, such as, but not limited to vacuum chucking, monopolar chucking, or bipolar chucking, depending on the operating regime of the processing tool.

In some embodiments, the processing tool may be suitable for thermal vapor deposition processes (i.e., without a plasma). Such processes may comprise chemical vapor deposition (CVD) or atomic layer deposition (ALD). Alternatively, the processing tool may include a plasma source to enable plasma enhanced operations, such as, plasma enhanced CVD (PE-CVD) or plasma enhanced ALD (PE-ALD). Furthermore, while embodiments disclosed herein are particularly suitable for the deposition of metal oxo photoresists for EUV patterning, it is to be appreciated that embodiments are not limited to such configurations. For example, the processing tools described herein may be suitable for depositing any photoresist material for any regime of lithography using a vapor phase process.

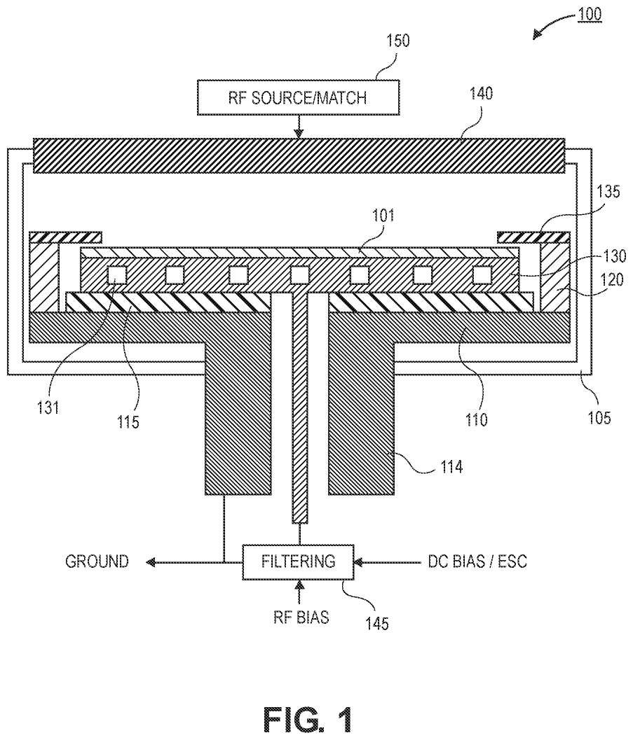

Referring now to FIG. 1, a cross-sectional illustration of a processing tool 100 is shown, in accordance with an embodiment. In an embodiment, the processing tool 100 may comprise a chamber 105. The chamber 105 may be any suitable chamber capable of supporting a sub-atmospheric pressure (e.g., a vacuum pressure). In an embodiment, an exhaust (not shown) that includes a vacuum pump may be coupled to the chamber 105 to provide a sub-atmospheric pressure. In an embodiment, a lid may seal the chamber 105. For example, the lid may comprise a showerhead assembly 140 or the like. The showerhead assembly 140 may include fluidic pathways to enable processing gasses and/or inert gasses to be flown into the chamber 105. In some embodiments where the processing tool 100 is suitable for plasma enhanced operation, the showerhead assembly 140 may be electrically coupled to an RF source and matching circuitry 150. In yet another embodiment, the tool 100 may be configured in an RF bottom fed architecture. That is, the pedestal 130 is connected to an RF source, and the showerhead assembly 140 is grounded. In such an embodiment, the filtering circuitry may still be connected to the pedestal.

In an embodiment, a displaceable column for supporting a wafer 101 is provided in the chamber 105. In an embodiment, the wafer 101 may be any substrate on which a photoresist material is deposited. For example, the wafer 101 may be a 300 mm wafer or a 450 mm wafer, though other wafer diameters may also be used. Additionally, the wafer 101 may be replaced with a substrate that has a non-circular shape in some embodiments. The displaceable column may include a pillar 114 that extends out of the chamber 105. The pillar 114 may have a port to provide electrical and fluidic paths to various components of the column from outside the chamber 105.

In an embodiment, the column may comprise a baseplate 110. The baseplate 110 may be grounded. As will be described in greater detail below, the baseplate 110 may comprise fluidic channels to allow for the flow of an inert gas to provide an edge purge flow.

In an embodiment, an insulating layer 115 is disposed over the baseplate 110. The insulating layer 115 may be any suitable dielectric material. For example, the insulating layer 115 may be a ceramic plate or the like. In an embodiment, a pedestal 130 is disposed over the insulating layer 115. The pedestal 130 may comprise a single material or the pedestal 130 may be formed from different materials. In an embodiment, the pedestal 130 may utilize any suitable chucking system to secure the wafer 101. For example, the pedestal 130 may be a vacuum chuck or a monopolar chuck. In embodiments where a plasma is not generated in the chamber 105, the pedestal 130 may utilize a bipolar chucking architecture.

The pedestal 130 may comprise a plurality of cooling channels 131. The cooling channels 131 may be connected to a fluid input and a fluid output (not shown) that pass through the pillar 114. In an embodiment, the cooling channels 131 allow for the temperature of the wafer 101 to be controlled during operation of the processing tool 100. For example, the cooling channels 131 may allow for the temperature of the wafer 101 to be controlled to between approximately −40° C. and approximately 300° C. In an embodiment, the pedestal 130 connects to the ground through filtering circuitry 145, which enables DC and/or RF biasing of the pedestal with respect to the ground.

In an embodiment, an edge ring 120 surrounds a perimeter of the insulating layer 115 and the pedestal 130. The edge ring 120 may be a dielectric material, such as a ceramic. In an embodiment, the edge ring 120 is supported by the base plate 110. The edge ring 120 may support a shadow ring 135. The shadow ring 135 has an interior diameter that is smaller than a diameter of the wafer 101. As such, the shadow ring 135 blocks the photoresist from being deposited onto a portion of the outer edge of the wafer 101. A gap is provided between the shadow ring 135 and the wafer 101. The gap prevents the shadow ring 135 from contacting the wafer 101, and provides an outlet for the edge purge flow that will be described in greater detail below.

While the shadow ring 135 provides some protection of the top surface and edge of the wafer 101, processing gasses may flow/diffuse down along a path between the edge ring 120 and the wafer 101. As such, embodiments disclosed herein may include an fluidic path between the edge ring 120 and the pedestal 130 to enable an edge purge flow. Providing an inert gas in the fluidic path increases the local pressure in the fluidic path and prevents processing gasses from reaching the edge of the wafer 101. Therefore, deposition of the photoresist is prevented along the edge of the wafer 101.

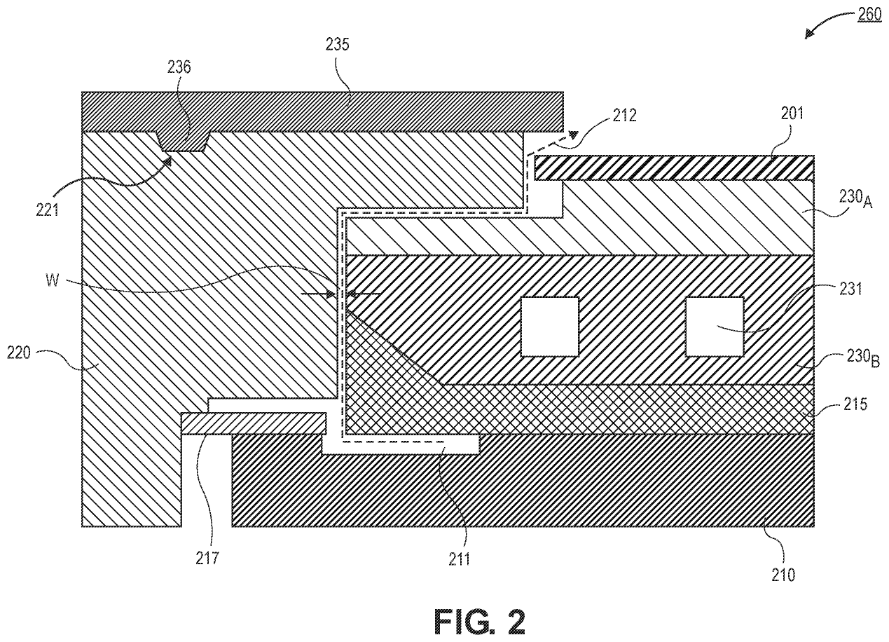

Referring now to FIG. 2, a zoomed in cross-sectional illustration of a portion of a column 260 within a processing tool is shown, in accordance with an embodiment. In FIG. 2, only the left edge of the column 260 is shown. However, it is to be appreciated that the right edge of the column 260 may substantially mirror the left edge.

In an embodiment, the column 260 may comprise a baseplate 210. An insulating layer 215 may be disposed over the baseplate 210. In an embodiment, the pedestal 230 may comprise a first portion 230A and a second portion 230_{B}. The cooling channels 231 may be disposed in the second portion 230_{B}. The first portion 230A may include features for chucking the wafer 201.

In an embodiment, an edge ring 220 surrounds the baseplate 210, the insulating layer 215, the pedestal 230, and the wafer 201. In an embodiment, the edge ring 220 is spaced away from the other components of the column 250 to provide a fluidic path 212 from the baseplate 210 to the topside of the column 260. For example, the fluidic path 212 may exit the column between the wafer 201 and shadow ring 235. In a particular embodiment, an interior surface of the fluidic path 212 comprises an edge of the insulating layer 215, an edge of the pedestal 230 (i.e., the first portion 230_{A} and the second portion 230_{B}), and an edge of the wafer 201. In an embodiment, the outer surface of the fluidic path 212 comprises an interior edge of the edge ring 220. In an embodiment, the fluidic path 212 may also continue over a top surface of a portion of the pedestal 230 as it progresses to the edge of the wafer 201. As such, when an inert gas (e.g., helium, argon, etc.) is flown through the fluidic path 212, processing gasses are prevented from flowing/diffusing down the side of the wafer 201.

In an embodiment, the width W of the fluidic path 212 is minimized in order to prevent the striking of a plasma along the fluidic path 212. For example, the width W of the fluidic path 212 may be approximately 1 mm or less. In an embodiment, a seal 217 blocks the fluidic path 212 from exiting the bottom of the column 260. The seal 217 may be positioned between the edge ring 220 and the baseplate 210. The seal 217 may be a flexible material, such as a gasket material or the like. In a particular embodiment, the seal 217 comprises silicone.

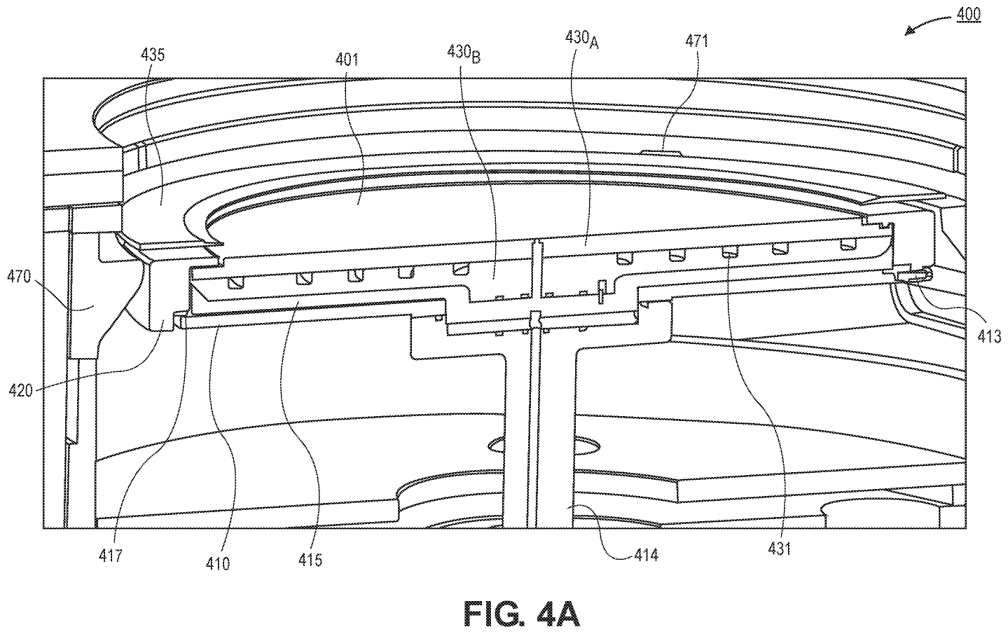

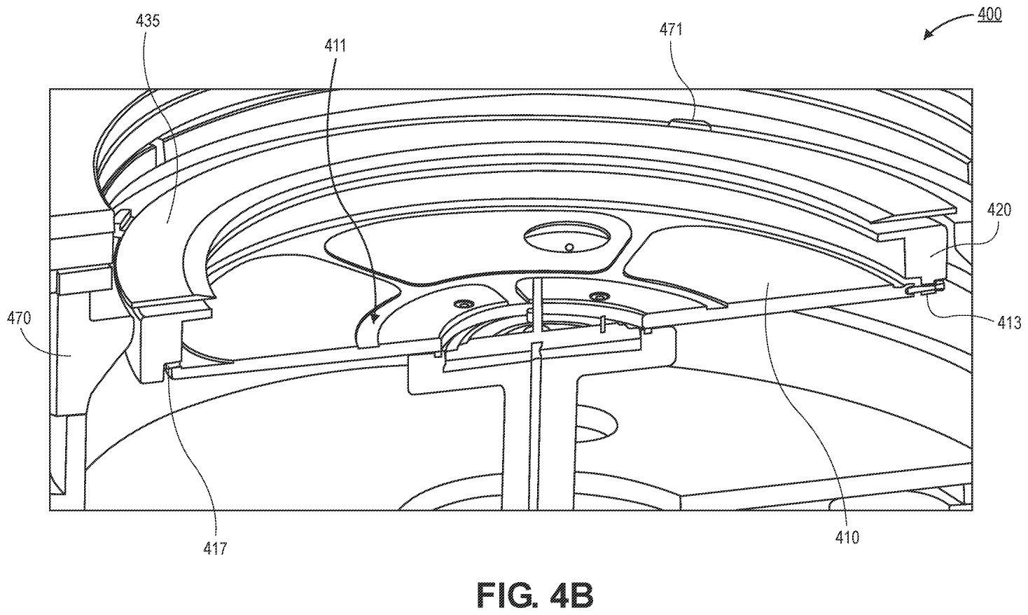

In an embodiment, a channel 211 is disposed in the baseplate 210. The channel 211 routes an inert gas from the center of the column 260 to the interior edge of the edge ring 220. It is to be appreciated that only a portion of the channel 211 is illustrated in FIG. 2. A more comprehensive illustration of the channel 211 is provided below with respect to FIG. 4B.

In an embodiment, the edge ring 220 and the shadow ring 235 may have features suitable for aligning the shadow ring 235 with respect to the wafer 201. For example, a notch 221 in the top surface of the edge ring 220 may interface with a protrusion 236 on the bottom surface of the shadow ring 235. The notch 221 and protrusion 236 may have tapered surfaces to allow for coarse alignment of the two components to be sufficient to provide a more precise alignment as the edge ring 220 is brought into contact with the shadow ring 235. In an additional embodiment, an alignment feature (not shown) may also be provided between the pedestal 230 and the edge ring 220. The alignment feature between the pedestal 230 and the edge ring 220 may comprise a tapered notch and protrusion architecture similar to the alignment feature between the edge ring 220 and the shadow ring 235.

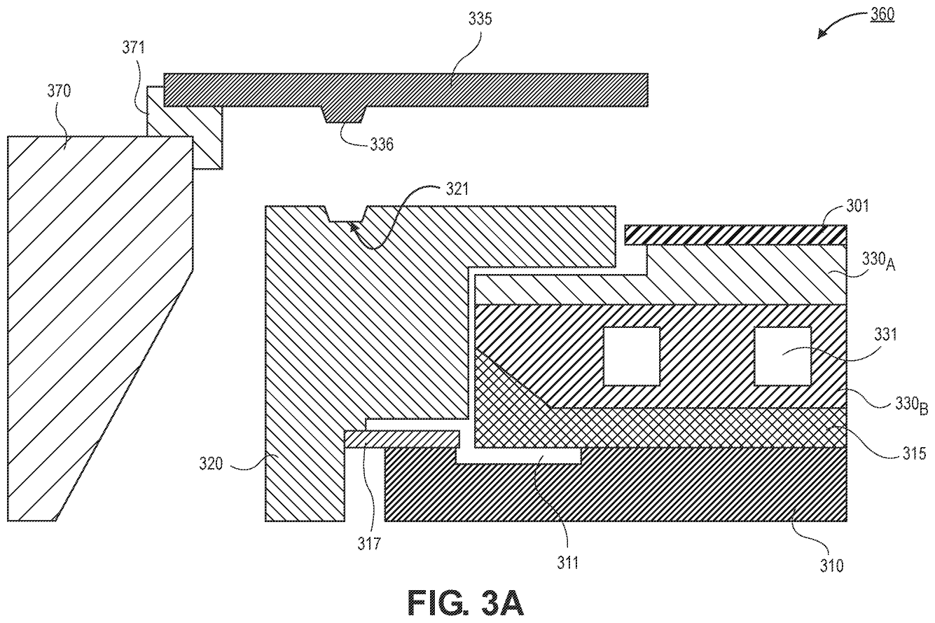

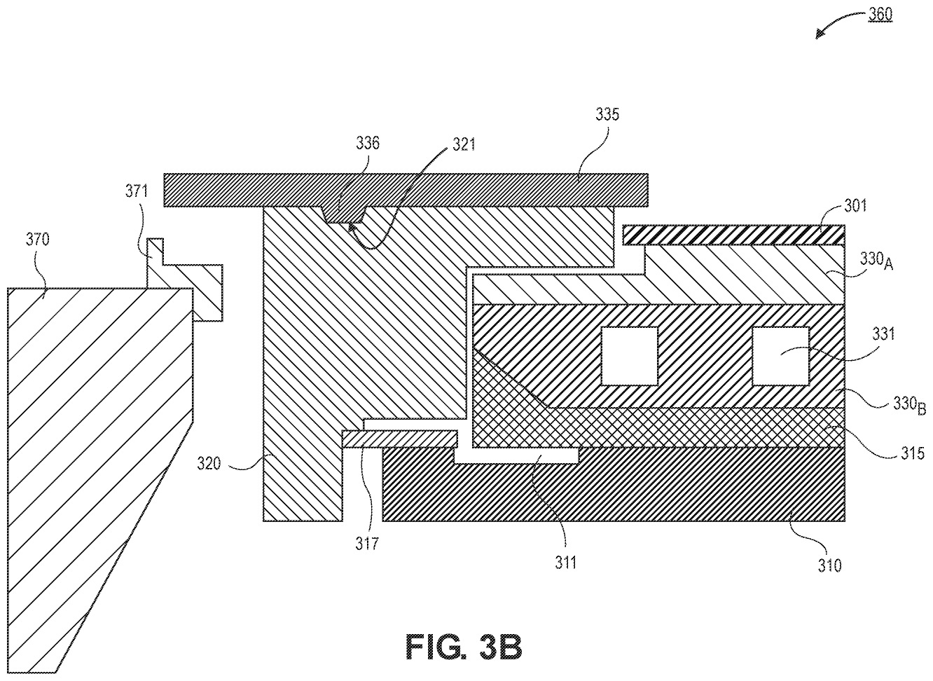

Referring now to FIGS. 3A and 3B, a pair of cross-sectional illustrations depicting portions of a processing tool with the pedestal at different locations (in the Z-direction) are shown, in accordance with an embodiment. In FIG. 3A, the pedestal is at a lower position within the chamber. The position of the pedestal in FIG. 3A is where the wafer is inserted or removed from the chamber through a slit valve. In FIG. 3B, the pedestal is at a raised position within the chamber. The position of the pedestal in FIG. 3B is where the wafer is processed.

Referring now to FIG. 3A, a cross-sectional illustration of a displaceable column 360 in a first position is shown, in accordance with an embodiment. As shown in FIG. 3A, the column comprises a baseplate 310, an insulating layer 315, a pedestal 330 (i.e., first portion 330_{A} and second portion 330_{B}), and an edge ring 320. Such components may be substantially similar to the similarly named components described above. For example, cooling channels 331 may be provided in the second portion 330_{B} of the pedestal 330, a channel 311 may be disposed in the baseplate 310, and a seal 317 may be provided between the edge ring 320 and the baseplate 310.

As shown in FIG. 3A, a wafer 301 is placed over a top surface of the pedestal 330. The wafer 301 may be inserted into the chamber through a slit valve (not shown). Additionally, the shadow ring 335 is shown at a raised position above the edge ring 320. Since the inner diameter of the shadow ring 335 is smaller than the diameter of the wafer 301, the wafer 301 needs to be placed on the pedestal before the shadow ring 335 is brought into contact with the edge ring 320.

In an embodiment, the shadow ring 335 is supported by a chamber liner 370. The chamber liner 370 may surround an outer perimeter of the column 360. In an embodiment, a holder 371 is positioned on a top surface of the chamber liner 370. The holder 371 is configured to hold the shadow ring 335 at an elevated position above the edge ring 320 when the column 360 is in the first position. In an embodiment, the shadow ring 335 comprises a protrusion 336 for aligning with a notch 321 in the edge ring 320.

Referring now to FIG. 3B, a cross-sectional illustration of the column 360 after the shadow ring 335 is engaged is shown, in accordance with an embodiment. As shown, the column 360 is displaced in the vertical direction (i.e., the Z-direction) until the shadow ring 335 engages the edge ring 320. Additional vertical displacement of the column 360 lifts the shadow ring 335 off of the holder 371 on the chamber liner 370. In an embodiment, the shadow ring 335 is aligned properly as a result of the alignment features in the shadow ring 335 and the edge ring 320 (i.e., the notch 321 and the protrusion 336). In an additional embodiment, an alignment feature (not shown) may also be provided between the pedestal 330 and the edge ring 320. The alignment feature between the pedestal 330 and the edge ring 320 may comprise a tapered notch and protrusion architecture similar to the alignment feature between the edge ring 320 and the shadow ring 335.

While in the second position, the wafer 301 may be processed. Particularly, the processing may include a vapor phase deposition of a photoresist material over a top surface of the wafer 301. For example, the process may be a CVD process, a PE-CVD process, an ALD process, or a PE-ALD process. In a particular embodiment, the photoresist is a metal oxo photoresist suitable for EUV patterning. However, it is to be appreciated that the photoresist may be any type of photoresist, and the patterning may include any lithography regime. During deposition of the photoresist onto the wafer 301, an inert gas may be flown along the fluidic channel between the interior surface of the edge ring 310 and the outer surfaces of the insulating layer 315, the pedestal 330, and the wafer 301. As such, photoresist deposition along the edge or backside of the wafer 301 is substantially eliminated. In an embodiment, the wafer 301 temperature may be maintained between approximately −40° C. and approximately 300° C. by the cooling channels 331 in the second portion of the pedestal 330_{B}. In an additional embodiment, the wafer 301 temperature may be between approximately −40° C. and approximately 200° C. In a particular embodiment, the wafer 301 temperature may be maintained at approximately 40° C.

Referring now to FIG. 4A, a sectional illustration of a processing tool 400 is shown, in accordance with an additional embodiment. As shown in FIG. 4A, the column comprises a baseplate 410. The baseplate 410 may be supported by a pillar 414 that extends out of the chamber. That is, in some embodiments, the baseplate 410 and the pillar 414 may be discrete components instead of a single monolithic part as shown in FIG. 1. The pillar 414 may have a central channel for routing electrical connections and fluids (e.g., cooling fluids and inert gasses for the purge flow).

In an embodiment, an insulating layer 415 is disposed over the baseplate 410, and a pedestal 430 (i.e., first portion 430_{A} and second portion 430_{B}) are disposed over the insulating layer 415. In an embodiment, coolant channels 431 are provided in the second portion 430_{B} of the pedestal 430. A wafer 401 is disposed over the pedestal 430.

In an embodiment, an edge ring 420 is provided around the baseplate 410, the insulating layer 415, the pedestal 430, and the wafer 401. The edge ring 420 may be coupled to the baseplate 413 by a fastening mechanism 413, such as a bolt, pin, screw, or the like. In an embodiment, a seal 417 blocks the purge gas from exiting the column out the bottom between a gap between the baseplate 410 and the edge ring 420.

In the illustrated embodiment, the pedestal 430 is in the first position. As such, the shadow ring 435 is supported by the holders 471 and the chamber liner 470. As the pedestal 430 is displaced vertically, the edge ring 420 will engage with the shadow ring 435 and lift the shadow ring 435 off of the holders 471.

Referring now to FIG. 4B, a sectional illustration of the chamber 400 is shown, in accordance with an additional embodiment. In the illustration of FIG. 4B, the insulating layer 415 and the pedestal 430 are omitted in order to more clearly see the construction of the baseplate 410. As shown, the baseplate 410 may comprise a plurality of channels 411 that provide fluidic routing from a center of the baseplate 410 to an edge of the baseplate 410. In the illustrated embodiment, a plurality of first channels connect the center of the baseplate 410 to a first ring channel, and a plurality of second channels connect the first ring channel to the outer edge of the baseplate 410. In an embodiment, the first channels and the second channels are misaligned from each other. While a specific configuration of channels 411 is shown in FIG. 4B, it is to be appreciated that any channel configuration may be used to route inert gasses from the center of the baseplate 410 to the edge of the baseplate 410.

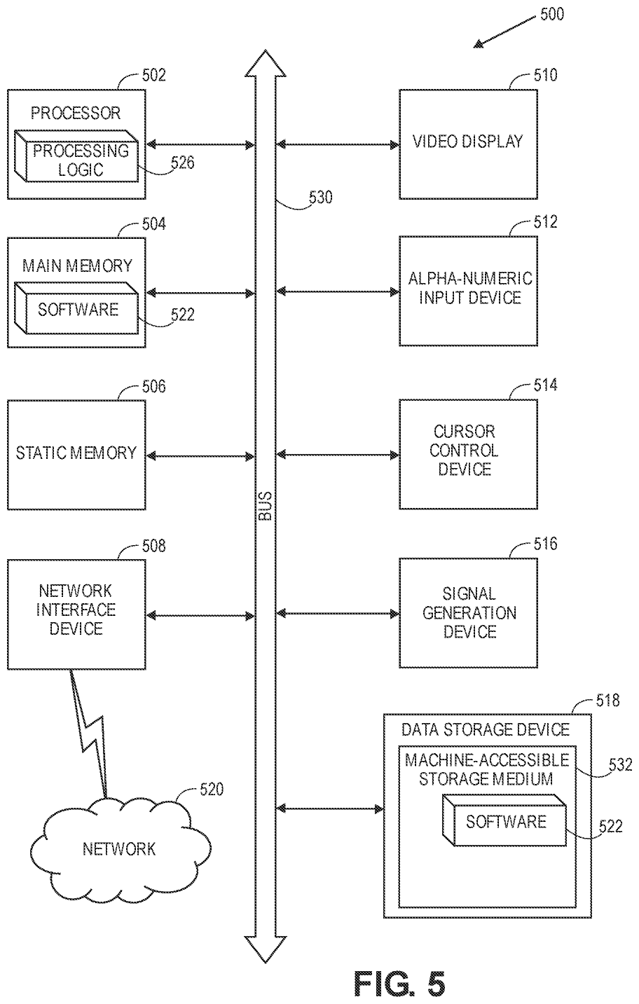

FIG. 5 illustrates a diagrammatic representation of a machine in the exemplary form of a computer system 500 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 500 includes a processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), MRAM, etc.), and a secondary memory 518 (e.g., a data storage device), which communicate with each other via a bus 530.

Processor 502 represents one or more general-purpose processing devices such as a microprocessor, central processing unit, or the like. More particularly, the processor 502 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 502 may also be one or more special-purpose processing devices such as an application specific integrated circuit (ASIC), a field programmable gate array (FPGA), a digital signal processor (DSP), network processor, or the like. Processor 502 is configured to execute the processing logic 526 for performing the operations described herein.

The computer system 500 may further include a network interface device 508. The computer system 500 also may include a video display unit 510 (e.g., a liquid crystal display (LCD), a light emitting diode display (LED), or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium (or more specifically a computer-readable storage medium) 532 on which is stored one or more sets of instructions (e.g., software 522) embodying any one or more of the methodologies or functions described herein. The software 522 may also reside, completely or at least partially, within the main memory 504 and/or within the processor 502 during execution thereof by the computer system 500, the main memory 504 and the processor 502 also constituting machine-readable storage media. The software 522 may further be transmitted or received over a network 520 via the network interface device 508.

While the machine-accessible storage medium 532 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

In accordance with an embodiment of the present disclosure, a machine-accessible storage medium has instructions stored thereon which cause a data processing system to perform a method of depositing a photoresist on a wafer. In an embodiment, the method comprises loading a wafer onto a pedestal through a slit valve in a chamber. The pedestal is then raised vertically. Raising the pedestal results in a shadow ring engaging an edge ring surrounding the pedestal. A photoresist may then be deposited on the wafer with a vapor phase process. During the photoresist deposition, an edge purge flow is provided around a perimeter of the wafer to prevent deposition of the photoresist on the edge or backside of the wafer.

Thus, methods of photoresist deposition using a vapor phase process with a tool that includes a shadow ring and an edge purge flow have been disclosed.

What is claimed is:

1. A semiconductor processing tool, comprising:
a chamber;
a displaceable column that passes through a surface of the chamber, wherein the column comprises:
a base plate;
an insulator layer over the base plate;
a pedestal over the insulator layer; and
an edge ring surrounding a perimeter of the ground plate, the insulator and the pedestal, wherein a fluidic path is provided between the edge ring and the pedestal.

2. The semiconductor processing tool of claim 1, further comprising:
a shadow ring over the edge ring.

3. The semiconductor processing tool of claim 2, wherein the shadow ring has a centering protrusion that interfaces with a centering notch in the edge ring.

4. The semiconductor processing tool of claim 1, wherein the pedestal comprises a plurality of channels configured to circulate a coolant in the pedestal that maintains a wafer temperature between approximately −40° C. and approximately 200° C.

5. The semiconductor processing tool of claim 1, further comprising:
channels disposed in a surface of the base plate, wherein the channels are fluidically coupled to the fluidic path.

6. The semiconductor processing tool of claim 1, further comprising:
a gasket between the edge ring and the ground plate.

7. The semiconductor processing tool of claim 1, wherein the fluidic path has a width that is approximately 1 mm or smaller.

8. The semiconductor processing tool of claim 1, wherein the pedestal is a bipolar chuck, a monopolar chuck, or a vacuum chuck.

9. The semiconductor processing tool of claim 1, further comprising:
a showerhead assembly above the column.

10. The semiconductor processing tool of claim 1, wherein the showerhead assembly is electrically coupled to an RF source.

11. The semiconductor processing tool of claim 1, wherein the base plate is grounded.

12. The semiconductor processing tool of claim 11, wherein the pedestal is coupled to an RF bias source and/or a DC bias source.

13. An assembly for holding a substrate in a semiconductor processing tool, wherein the assembly comprises:
a base plate;
an insulating layer over the base plate;
a pedestal over the insulating layer;
an edge ring around a perimeter of the base plate, the insulating layer, and the pedestal; and
a fluidic path from the bottom of the assembly to the top of the assembly, wherein the fluidic path passes through a first channel between the base plate and the insulating layer, through a second channel between the edge ring and the insulating layer, and through a third channel between the edge ring and the pedestal.

14. The assembly of claim 13, wherein a width of the second channel and a width of the third channel is approximately 1 mm or smaller.

15. The assembly of claim 13, further comprising:
a gasket between the base plate and the edge ring, wherein the gasket is exposed to a portion of the fluidic path.

16. The assembly of claim 13, further comprising:
a shadow ring over the edge ring.

17. The assembly of claim 16, wherein the shadow ring has a centering protrusion that interfaces with a centering notch in the edge ring.

18. A semiconductor processing tool, comprising:
a chamber;
a showerhead assembly that seals the chamber, wherein the showerhead assembly is electrically coupled to an RF source;
a displaceable column that passes through the chamber and is opposite from the showerhead assembly, wherein the column comprises:
a base plate;
an insulator layer over the base plate;
a pedestal over the insulator layer; and
an edge ring surrounding a perimeter of the ground plate, the insulator and the pedestal, wherein a fluidic path is provided between the edge ring and the pedestal.

19. The semiconductor processing tool of claim 18, further comprising:
a liner surrounding the edge ring; and
a shadow ring.

20. The semiconductor processing tool of claim 19, wherein the shadow ring is supported by the liner when the column is in a first position relative to the showerhead assembly, and wherein the shadow ring is supported by the edge ring when the column is in a second position relative to the showerhead assembly, wherein the pedestal is closer to the showerhead assembly when the column is in the second position than when the column is in the first position.
